(19) United States
(12) Patent Application Publication
(10) Pub. No.: US 2013/0032904 A1
(43) Pub. Date: Feb. 7, 2013

(54) Coated Capacitive Sensor

(71) Applicants: Ando Feyh, Palo Alto, CA (US); Johannes Classen, Reutlingen (DE)

(72) Inventors: Ando Feyh, Palo Alto, CA (US); Johannes Classen, Reutlingen (DE)

(73) Assignee: ROBERT BOSCH GMBH, Stuttgart (DE)

(21) Appl. No.: 13/197,981

(22) Filed: Aug. 4, 2011

(51) Int. Cl. H01L 29/84; H01L 21/00

(52) U.S. Cl. 257/415; 438/50; 257/E29.324; 257/E21.001

(57) ABSTRACT

In one embodiment, a method of forming a MEMS device includes providing a substrate, forming a sacrificial layer above the substrate layer, forming a silicon based working portion on the sacrificial layer, releasing the silicon based working portion from the sacrificial layer such that the working portion includes at least one exposed outer surface, forming a first layer of silicide forming metal on the at least one exposed outer surface of the silicon based working portion, and forming a first silicide layer with the first layer of silicide forming metal.

### FIELD

This invention relates to micro-machined capacitive sensors and methods of fabricating such devices.

### BACKGROUND

Surface micromachining is used to fabricate many microelectromechanical system (MEMS) devices. With surface micromachining, a MEMS device structure can be built on a silicon substrate using processes such as chemical vapor deposition. These processes allow MEMS structures to include layer thicknesses of less than a few microns with substantially larger in-plane dimensions. Frequently, these devices include parts which are configured to move with respect to other parts of the device. In this type of device, the movable structure is frequently built upon a sacrificial layer of material. After the movable structure is formed, the movable structure can be released by selective wet etching of the sacrificial layers in aqueous hydrofluoric acid (HF). After etching, the released MEMS device structure can be rinsed in deionized water to remove the etchant and etch products.

Due to the large surface area-to-volume ratio of many movable structures, a MEMS device including such a structure is susceptible to interlayer or layer-to-substrate adhesion during the release process (release adhesion) or subsequent device use (in-use adhesion). This adhesion phenomenon is more generally called stiction. Stiction is exacerbated by the ready formation of a 5-30 angstrom thick native oxide layer on the silicon surface, either during post-release processing of the MEMS device or during subsequent exposure to air during use. Silicon oxide is hydrophilic, encouraging the formation of water layers on the native oxide surfaces that can exhibit strong capillary forces when the small interlayer gaps are exposed to a high humidity environment. Furthermore, Van der Waals forces, due to the presence of certain organic residues, hydrogen bonding, and electrostatic forces, also contribute to the interlayer attraction. These cohesive forces can be strong enough to pull the free-standing released layers into contact with another structure, causing irreversible latching and rendering the MEMS device inoperative.

Various approaches have been used in attempts to minimize adhesion in MEMS devices. These approaches include drying techniques, such as freeze-sublimation and supercritical carbon dioxide drying, which are intended to prevent liquid formation during the release process, thereby preventing capillary collapse and release adhesion. Vapor phase HF etching is commonly used to alleviate in-process stiction. Other approaches are directed to reducing stiction by minimizing contact surface areas, designing MEMS device structures that are stiff in the out-of-plane direction, and hermetic packaging.

An approach to reducing in-use stiction and adhesion issues is based upon surface modification of the device by addition of an anti-stiction coating. The modified surface ideally exhibits low surface energy by adding a coating of material, thereby inhibiting in-use adhesion in released MEMS devices. Most coating processes have the goal of producing a thin surface layer bound to the native silicon oxide that presents a hydrophobic surface to the environment. In particular, coating the MEMS device surface with self-assembled monolayers (SAMs) having a hydrophobic tail group has been shown to be effective in reducing in-use adhesion. SAMs have typically involved the deposition of organosilane coupling agents, such as octadecyltrichlorosilane and perfluorodecyltrichlorosilane, from nonaqueous solutions after the MEMS device is released. Even without anti-stiction coating, native oxide generation occurs on silicon surfaces.

In spite of these various approaches, in-use adhesion remains a serious reliability problem with MEMS devices. One aspect of the problem is that even when an antistiction coating is applied, the underlying silicon layer may retain various charges. For example, silicon by itself is not a conductor. In order to modify a silicon structure to be conductive, a substance is doped into the silicon. The realizable doping-level is limited, however, due to induced stress in the functional silicon layer. Accordingly, during manufacturing process, charges are deposited on the silicon surfaces of sensing elements and the charges do not immediately migrate. The charges include dangling bonds due to trench forming processes used to define various structures. In capacitive sensing devices those charges may cause a reliability issue since they are not all locally bound. Some charges have a certain mobility and may drift as a function of temperature or aging. This can lead to undesired drift effects, e.g. of the sensitivity or offset of the capacitive sensor. Therefore, a highly conductive working layer (not possible w/ silicon) or at least a highly conductive coating on top of the structures in order to not accumulate surface charges would be desirable.

Moreover, the limited conductivity of silicon may result in unacceptable RC time constants in electronic evaluation circuits including capacitive sensors. A sensor element with, e.g., a 10 pF total capacitance (C) and 10 kOhm total resistance (R) may be limited to operation below frequencies of about 1 MHz. Operation at higher frequencies is desired in certain applications, however, since higher frequency operation may lead to a better signal to noise performance of the sensor. Therefore, increased conductivity in MEMS devices which enable achievement of lower RC time constants would be beneficial.

Thus, there remains a need for a reliable coating for MEMS devices that is compatible with MEMS fabrication processes that can be used to reduce stiction forces, surface charges, and/or the resistivity of MEMS structures.

### SUMMARY

In accordance with one embodiment, a method of forming a MEMS device includes providing a substrate, forming a sacrificial layer above the substrate layer, forming a silicon based working portion on the sacrificial layer, releasing the silicon based working portion from the sacrificial layer such that the working portion includes at least one exposed outer surface, forming a first layer of silicide forming metal on the at least one exposed outer surface of the silicon based working portion, and forming a first silicide layer with the first layer of silicide forming metal.

In a further embodiment, a MEMS device includes a released silicon based working portion, and a first silicide layer on all otherwise exposed surfaces of the silicon based working portion.

### BRIEF DESCRIPTION OF THE DRAWINGS

FIG. 1 depicts a side cross-sectional view of a capacitive sensor device with a silicide layer formed on otherwise exposed surfaces of the working portion of the device in accordance with principles of the present invention;

FIG. 2 depicts a side cross-sectional view of a capacitive sensor device like the device of FIG. 1 before a silicide layer is formed on exposed surfaces of the working portion of the device;

FIG. 3 depicts a side cross-sectional view of the device of FIG. 2 after a conformal layer of silicide forming material has been deposited on all otherwise exposed surfaces of the device; and

FIG. 4 depicts a side cross-sectional view of the device of FIG. 3 after annealing has resulted in the formation of silicide layers on otherwise exposed surfaces which included silicon.

### DESCRIPTION

For the purposes of promoting an understanding of the principles of the invention, reference will now be made to the embodiments illustrated in the drawings and described in the following written specification. It is understood that no limitation to the scope of the invention is thereby intended. It is further understood that the present invention includes any alterations and modifications to the illustrated embodiments and includes further applications of the principles of the invention as would normally occur to one skilled in the art to which this invention pertains.

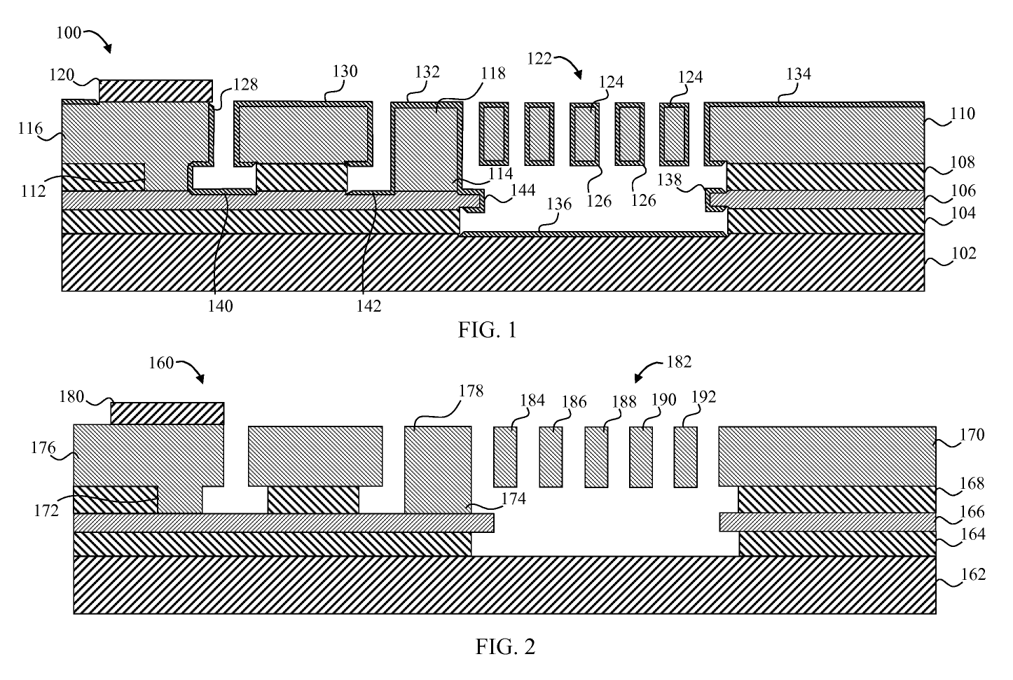

A MEMS sensor 100 is depicted in FIG. 1. The MEMS sensor 100 includes a substrate 102, a lower oxide sacrificial layer 104, a buried silicon layer 106, an upper sacrificial oxide layer 108, and a working layer 110. The substrate 102 may be a complementary metal oxide semiconductor (CMOS) substrate or on another type of substrate. The substrate 102, which in this embodiment is a silicon wafer, may include one or more sensors 100.

The lower oxide layer 104, which may be thermally grown, functions as an insulator layer between the buried silicon layer 106 and the substrate 102. The upper oxide layer 108, which may be deposited, e.g., within a plasma-enhanced chemical vapor deposition (PECVD) process, functions as an insulator layer between the buried silicon layer 106 and the working layer 110. Electrical communication between the buried silicon layer 106 and portions of the working layer 110 is provided by columns 112/114 which extend through trenches formed in the upper sacrificial oxide layer 108. The buried silicon layer 106 thus provides for electrical communication between various components formed in the working layer 110 through the columns 112/114.

The working layer 110 includes an electrode portion 116 and an anchor portion 118 which are fixedly positioned with respect to the substrate 102. A contact 120 is located on an upper surface of the electrode portion 116. The contact 120 may be formed of a metallic material.

The anchor portion 118 supports a working portion 122 by structure not shown in FIG. 1. The support structure (not shown) may be, for example, a cantilever arm. A “working portion” as that term is used herein means a portion of the MEMS sensor 100 that is intended to move with respect to the substrate 102 during normal operation of the MEMS sensor 100. The working portion 122 in the embodiment of FIG. 1 is a capacitive member which moves within the plane of the working layer 110. In other embodiments, a working portion may be configured for out of plane movement.

The working portion 122 includes an inner portion 124 and a silicide layer 126 located on the outer surface of the working portion 122. In the embodiment of FIG. 1, additional silicide layers 128, 130, 132 and 134 are formed on the otherwise exposed portions of the outer surfaces of the working layer 110. The term “otherwise exposed” means portions of the outer surface of a component that would be exposed if an associated silicide layer (or silicide forming metal, discussed further below) was removed from the outer surface such that no portion of the component was in contact with a silicide or a silicide forming metal. Thus, the portion of the working layer 110 directly beneath the contact 120 would not be “otherwise exposed”. Likewise, the lower surface of the electrode portion 116 which abuts the buried silicon layer 106 and that which joins with the column 112 would not be “otherwise exposed”.

In the embodiment of FIG. 1, a silicide layer 136 is also formed on an otherwise exposed portion of the substrate 102 and a silicide layer 138 is formed on an otherwise exposed portion of the buried silicon layer 106. The silicide layer 128 also includes a portion 140 that is formed on an otherwise exposed portion of the buried silicon layer 106. Additionally, the silicide layer 132 includes a portion 142 and a portion 144 that are formed on otherwise exposed portions of the buried silicon layer 106.

The device of FIG. 1 may be manufactured using any desired approach which initially results in a movable portion of a silicon based material. By way of example, FIG. 2 depicts a MEMS sensor 160 without any silicide layers that may be produced using desired manufacturing processes. The MEMS sensor 160 includes a substrate 162, a lower oxide sacrificial layer 164, a buried silicon layer 166, an upper sacrificial oxide layer 168, and a working layer 170.

Columns 172/174 extend through trenches formed in the upper sacrificial oxide layer 168. The column 172 is integrally formed with an electrode portion 176 and column 174 is integrally formed with an anchor portion 178. The electrode portion 176 and the anchor portion 178 are fixedly positioned with respect to the substrate 162. A contact 180 is located on an upper surface of the electrode portion 176.

The anchor portion 178 supports a working portion 182 by structure not shown in FIG. 2. The working portion 182 is configured to move with respect to the substrate 162 during normal operation of the MEMS sensor 160. The working portion 182 includes a number of fingers 184, 186, 188, 190, and 192. The outer surface of each of the fingers 184, 186, 188, 190, and 192 as viewed in FIG. 2 is fully exposed.

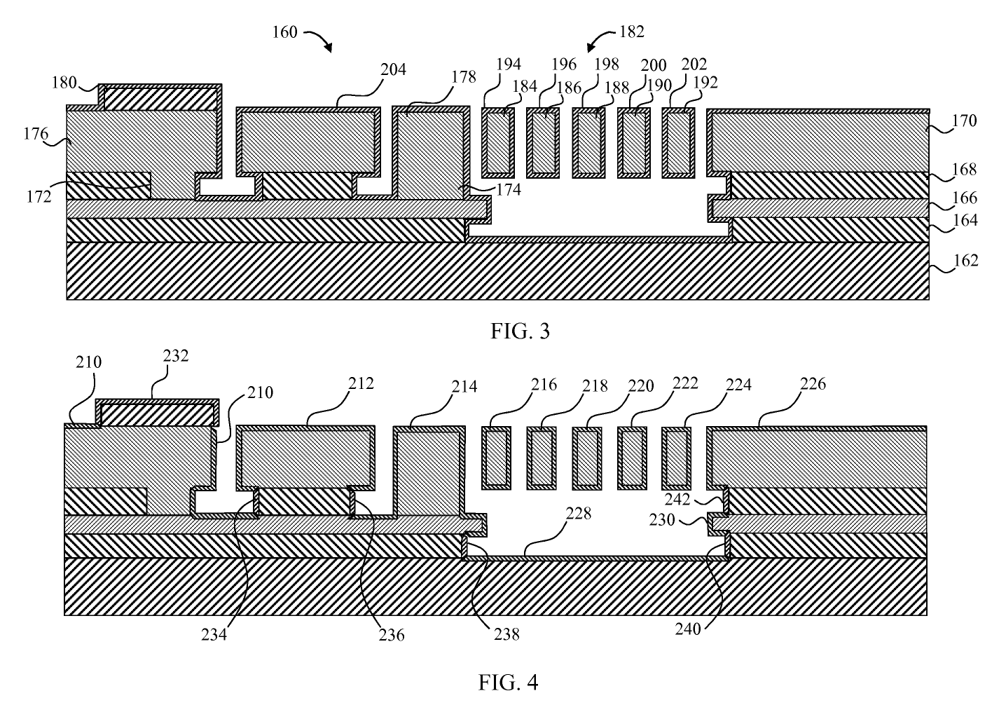

Once the working portion 182 has been released by etching of the upper sacrificial layer 168, a conformal coating of a silicide forming material is applied to the working portion 182. The resulting configuration is shown in FIG. 3 wherein the fingers 184, 186, 188, 190, and 192 each have a respective silicide forming layer portion 194, 196, 198, 200, and 202 deposited on the otherwise exposed outer surfaces. Each of the silicide forming layer portions 194, 196, 198, 200, and 202 are a portion of a single conforming layer 204 of silicide forming material which coats every otherwise exposed portion of the components of the device 160.

A silicide forming material is a material that reacts with silicon (Si) in the presence of heat to form a silicide compound including the silicide forming material and silicon. Some common metals in this category include nickel (Ni), titanium (Ti), cobalt (Co), molybdenum (Mo), and platinum (Pt). The conforming layer 204 may be formed by atomic layer deposition (ALD) of the silicide forming material. ALD is used to deposit materials by exposing a substrate to several different precursors sequentially. A typical deposition cycle begins by exposing a substrate is to a precursor “A” which reacts with the substrate surface until saturation. This is referred to as a “self-terminating reaction.” Next, the substrate is exposed to a precursor “B” which reacts with the surface until saturation. The second self-terminating reaction reactivates the surface. Reactivation allows the precursor “A” to react with the surface. Typically, the precursors used in ALD include an organometallic precursor and an oxidizing agent such as water vapor or ozone.

The deposition cycle results, ideally, in one atomic layer being formed. Thereafter, another layer may be formed by repeating the process. Accordingly, the final thickness of the conforming layer 204 is controlled by the number of cycles a substrate is exposed to. Moreover, deposition using an ALD process is substantially unaffected by the orientation of the particular surface upon which material is to be deposited. Accordingly, an extremely uniform thickness of material may be realized both on the upper and lower horizontal surfaces and on the vertical surfaces.

After the desired amount of silicide forming metal has been deposited on the otherwise exposed surfaces of the working portion 182, and any other silicon-containing surfaces on which a silicide layer is desired, the MEMS sensor 160 is subjected to heat, such as by performing a rapid thermal annealing (RTA) process. The temperature at which the annealing is done, along with the time at which the temperature is maintained, is determined based upon the particular silicide forming material as well as the thickness of the desired silicide layer. Nominally, a temperature of between 250° C. and 800° C. is sufficient, with the anneal lasting for between about one second and one minute. For some applications, an annealing temperature of less than 450° C. is desirable. A number of silicide forming materials have a silicidation temperature of less than 450° C. By way of example, when Ni is used as a silicide material in the presence of Si at a silicidation temperature of about 250° C., Ni₂Si is formed.

Some silicide forming materials exhibit volume shrinkage during silicidation. “Volume shrinkage” is a phenomenon wherein the volume of the formed silicide is less than the volume of the initial silicon and silicide forming material. Each of the metals identified above exhibit this phenomenon when used to form a silicide. By way of example, the Ni₂Si compound described above occupies 23% less volume than the volume of the original Si and Ni material. Accordingly, the initial dimensions of the components of the MEMS sensor 160 should be selected based upon an understanding of the size modification for a particular silicide forming material when silicide forming materials which exhibit volume shrinkage are used.

When the conforming layer 204 is subjected to heat, the portions of the conforming layer 204 which have a supply of silicon available will be converted to a silicide layer with the portion of the conforming layer 204 and some of the silicon from the abutting silicon-laden component being consumed. Thus, after annealing, the configuration of FIG. 4 is obtained. In FIG. 4, silicide portions 210, 212, 214, 216, 218, 220, 222, 224, 226, 228, and 230 are formed since the surface upon which the silicide portions 210-230 are formed are able to donate silicon. Portions of the conforming layer 204 which are deposited on surfaces without donor silicon, however, are not converted. Thus, portions 232, 234, 236, 238, 240, and 242 of the silicide forming layer 204 remain as silicide forming materials. The portions 232, 234, 236, 238, 240, and 242 may then be etched away resulting in the configuration of the device 100 of FIG. 1.

The basic process set forth above may be modified in a number of ways depending upon the particular embodiment. By way of example, in embodiments wherein the silicide layer that is formed is a conductive layer, the silicide layer itself may be used as a contact. Thus, the contact 120 in the embodiment of FIG. 1 may be omitted and the silicide layer 128 may be used as a contact.

Additionally, it may be desirable to not coat some silicon-based components with a silicide layer. In such embodiments, the component may be masked or covered by a sacrificial material until after the silicide forming material is deposited.

While the invention has been illustrated and described in detail in the drawings and foregoing description, the same should be considered as illustrative and not restrictive in character. It is understood that only the preferred embodiments have been presented and that all changes, modifications and further applications that come within the spirit of the invention are desired to be protected.

1. A method of forming a MEMS device comprising:
providing a substrate;
forming a sacrificial layer above the substrate layer;
forming a silicon based working portion on the sacrificial layer;
releasing the silicon based working portion from the sacrificial layer such that the working portion includes at least one exposed outer surface;
forming a first layer of silicide forming metal on the at least one exposed outer surface of the silicon based working portion; and
forming a first silicide layer with the first layer of silicide forming metal.

2. The method of claim 1, wherein forming a first layer of silicide forming metal comprises:
forming the first layer of silicide forming metal on all exposed outer surfaces of the silicon based working portion.

3. The method of claim 2, wherein forming a first layer of silicide forming metal comprises:
forming the first layer of silicide forming metal by atomic layer deposition (ALD).

4. The method of claim 2, further comprising:
etching a residual portion of silicide forming metal after forming the first silicide layer.

5. The method of claim 4, wherein forming a first silicide layer comprises:
heating the first layer of silicide forming metal by rapid thermal annealing (RTA).

6. The method of claim 5, wherein heating the first layer of silicide forming metal comprises:
heating the first layer of silicide forming metal to a temperature of between about 250° C. and about 800° C.

7. The method of claim 5, wherein heating the first layer of silicide forming metal comprises:
heating the first layer of silicide forming metal to a temperature of less than about 450° C.

8. The method of claim 2, further comprising:
forming a bond area by forming a second silicide layer.

9. The method of claim 2, further comprising:
applying an organic anti-stiction coating to the first silicide layer.

10. A MEMS device comprising:
a released silicon based working portion; and
a first silicide layer on all otherwise exposed surfaces of the silicon based working portion.

11. The MEMS of claim 10, wherein the first silicide layer is formed by atomic layer deposition (ALD) of a silicide forming metal on the released silicon based working portion with subsequent annealing to form a silicide.

12. The MEMS of claim 10, further comprising:
a silicon based substrate with an otherwise exposed portion beneath the released silicon based working portion; and
a second silicide layer on the otherwise exposed portion of the silicon based substrate.

13. The MEMS of claim 10, wherein the released silicon based working portion is defined in a silicon based working layer, the MEMS device further comprising:
an anchor portion defined in the silicon based working layer; and
a second silicide layer on all otherwise exposed surfaces of the anchor portion.

14. The MEMS of claim 13, further comprising:
a bond pad formed on an upper surface of a bond portion of the silicon based working layer; and
a third silicide layer on all otherwise exposed surfaces of the bond portion.

15. The MEMS of claim 13, further comprising:
a bond portion defined in the silicon based working layer; and
a third silicide layer on all otherwise exposed surfaces of the bond portion.

16. The MEMS device of claim 10, further comprising:
an organic anti-stiction coating applied to the first silicide layer.
